(19) United States
(12) Patent Application Publication
(10) Pub. No.: US 2014/0175437 A1
(43) Pub. Date: Jun. 26, 2014

(54) Oxide Semiconductor Device and Surface Treatment Method of Oxide Semiconductor

(71) Applicant: Hitachi, Ltd., Tokyo (JP)

(72) Inventor: Hiroyuki UCHIYAMA, Musashimurayama (JP)

(73) Assignee: Hitachi, Ltd., Tokyo (JP)

(21) Appl. No.: 14/191,598

(22) Filed: Feb. 27, 2014

Related U.S. Application Data
(63) Continuation of application No. 12/329,649, filed on Dec. 8, 2008.

(30) Foreign Application Priority Data
Dec. 26, 2007 (JP) 2007-333865

(51) Int. Cl. H01L 29/786

(52) U.S. Cl. CPC H01L 29/7869
USPC 257/43

(57) ABSTRACT

Oxygen defects formed at the boundary between the zinc oxide type oxide semiconductor and the gate insulator are terminated by a surface treatment using sulfur or selenium as an oxygen group element or a compound thereof, the oxygen group element scarcely occurring physical property value change. Sulfur or selenium atoms effectively substitute oxygen defects to prevent occurrence of electron supplemental sites by merely applying a gas phase or liquid phase treatment to an oxide semiconductor or gate insulator with no remarkable change on the manufacturing process. As a result, this can attain the suppression of the threshold potential shift and the leak current in the characteristics of a thin film transistor.

### CROSS-REFERENCE TO RELATED APPLICATIONS

This application is a divisional application of U.S. Ser. No. 12/329,649, filed Dec. 8, 2008, the entire content of which is incorporated herein by reference.

### CLAIM OF PRIORITY

The present application claims priority from Japanese patent application JP 2007-333865 filed on Dec. 26, 2007, the content of which is hereby incorporated by reference into this application.

### BACKGROUND OF THE INVENTION

1. Field of the Invention

The present invention relates to an oxide semiconductor device and a surface treatment method thereof and it particularly relates to a technique of improving the reliability of a thin-film transistor which is utilized as a switching device for liquid crystal televisions and organic EL televisions, a driver device and a basic element for RFID (Radio Frequency Identification) tags.

2. Description of the Related Arts

In recent years, display devices have been developed rapidly from displays using a cathode-ray-tube to a flat type display device referred to as a flat panel display (FPD) such as a liquid crystal panel and a plasma display panel. In liquid crystal panels, a-Si or polysilicon thin-film transistors have been utilized as a switching device which concerns switching of display by liquid crystals. Recently, FPD using an organic EL has been expected with an aim of further increasing the picture area and making the structure flexible.

However, since the organic El display is a self-emitting display for directly obtaining emission by driving an organic semiconductor layer, characteristics as a current driving device have been required for thin-film transistors, which is different from existent liquid crystal displays. On the other hand, provision of new functions such as further increase of the picture area and more flexible structure is also demanded for FPD in the future and it is required to have a high performance as an image displays device, as well as to correspond to a large picture area process and a flexible substrate. With the background as described above, for thin-film transistors intended for display devices, application of transparent oxide semiconductors having a band gap as large as about 3 eV have been studied in recent years, and they are also expected for application use to RFID, etc, as well as to display devices.

For example, JP-A Nos. 2007-073563 and 2007-073558, and JP-T No. 2006-502597, etc, disclose a method of using zinc oxide as an oxide semiconductor, and increasing an oxygen partial pressure during and after film formation of a zinc oxide semiconductor or applying oxygen annealing or oxygen plasma processing in order to suppress the shift of threshold potential, leak current and deterioration of characteristics due to the presence of crystal grain boundaries, which are drawbacks of zinc oxide. However, since zinc oxide is a material for which stoichiometrical control is extremely difficult, while satisfactory characteristics are obtained just after using the methods described above, deterioration of characteristics often proceeds with lapse of time.

Further, JP-A No. 2006-186319 discloses a thin-film transistor using a-IGZO (amorphous-indium gallium zinc oxide) as a material capable of suppressing the shift of a threshold potential as the drawback of zinc oxide. However, since this thin film transistor uses indium and gallium as a noble metal source, the cost of which has been increased in recent years, and since indium is an element causing health hazard such as interstitial pneumonia, it leaves a problem in future application to practical use.

### SUMMARY OF THE INVENTION

For display control of the organic EL display described above, a thin-film transistor is applied as in the case of the liquid crystal display. While the existent liquid crystal device has only the function of switching, a function as a driver for driving current is required in addition to the switching operation in an organic EL device. Since a large load is applied on a current driving device, a high reliability is required in view of the threshold potential shift and durability. For example, in a-Si used mainly for the switching of existent liquid crystal displays, since the shift of the threshold potential greatly exceeds the level of about 2 V which can be controlled easily by a compensation circuit, it is considered difficult to be applied as a thin-film transistor for the organic EL device. Further, while polysilicon applied to small-to-medium sized displays has sufficient characteristics for driving organic EL device, it is difficult to be applied to large-scale FPDs in the future in view of a problem of process throughput.

Then, studies have now been made on an oxide semiconductor which is capable of large picture area processing by a sputtering method or a CDV method, capable of obtaining a high mobility of about 1 to 50 cm²/Vs and is advantageous in view of the shift of threshold potential and environmental stability. In particular, while various studies have been made mainly on zinc oxide type oxide semiconductors, it has been known for zinc oxide that control for the grain boundary due to the presence of rotational domains during film formation or control for stoichiometrical amount is difficult, and oxygen defects are present. The oxygen defects cause lowering of mobility, shift of threshold potential, leak current, etc. as sites for supplementing electrons and involve a problem not capable of taking the advantage inherent in wide gap oxide semiconductors. Then, while amorphous type oxide semiconductor materials such as a-IGZO capable of suppressing the threshold potential shift have also been proposed, since they use rare metals of indium and gallium the cost of which has been increased in recent years, they involve a problem in view of the resource. Further, indium also involves a problem of health hazard as an element causing interstitial pneumonia, it leaves a problem in the future application.

The present invention intends to provide, in a zinc oxide type oxide semiconductor which is prospecting as a switching and driving thin-film transistor for organic EL displays or liquid crystal displays in the next generation and is also prospecting in view of the resource and envelopment, a surface treatment technique of effectively suppressing the threshold potential shift and occurrence of leak current caused by oxygen defects present at the boundary between an oxide semiconductor and a gate insulator, and fluctuation of device characteristics caused by moisture or gas adsorption, as well as the device using the technique.

The outline of typical invention among those disclosed in the present application is to be described simply as below.

In the oxide semiconductor device and the surface treatment method of the oxide semiconductor according to the invention, a surface treatment is performed to the boundary between the oxide semiconductor and the gate insulator with an oxygen group element such as sulfur or selenium or a compound containing them having crosslinking bondability to passivate the sites where oxygen defects have been formed. Similar surface treatment has been applied by conducting surface passivation by removing an oxide for stabilizing the surface of a gallium arsenide type compound semiconductor (Japanese Journal of Applied Physics, 1988, Vol. 27, No. 12, p L2367 to p L2369). In the present invention, however, sulfur or selenium is used as a substitution element for oxygen defect presents between the oxide semiconductor and the gate insulator. Since Sulfur or Selenium is the oxygen group element, the physical property is less changed by the introduction of the element to attain preferred terminating treatment and electron supplementing sites by oxygen defects can be decreased. In particular, since ZnO and ZnS have identical crystal form of Wurtzite crystal as shown in FIG. 1 and their band gaps are similar as 3.24 eV and 3.68 eV respectively, the problem of oxygen defects can be suppressed by sulfur with scarce effects on the characteristics of the ZnO type oxide semiconductor. The zinc oxide type oxide semiconductor has an oxygen defect density of about 10¹⁸ to 10² cm⁻³ and shows characteristics close to a conductor. An introduction density of the element about 10¹⁶ to 10²⁰ cm⁻³ is necessary for compensating the oxygen defects, particularly, for suppressing the off current.

The effects obtained by typical invention among those disclosed in the present application are to be simply described as below.

The reliability in the operation of display devices, RFID tags, flexible devices and other devices for which the other oxide semiconductors are applied can be improved by suppressing the threshold potential shift, occurrence of leak current due to oxygen defects present at the boundary between the oxide semiconductor and the gate insulator, and degradation of characteristics due to envelopment.

### BRIEF DESCRIPTION OF THE DRAWINGS

FIG. 1 is a chart for comparing physical property values of oxygen group zinc compound used in the invention and physical property value of zinc oxide;

FIG. 2 is a cross sectional view showing the structure of a bottom gate type oxide semiconductor thin-film transistor according to a first embodiment of the invention;

FIGS. 3A to 3G show cross sectional views showing steps of manufacturing a bottom gate type oxide semiconductor thin-film transistor according to the first embodiment of the invention;

FIG. 4 is a cross sectional view showing the structure of a top gate type oxide semiconductor thin-film transistor according to the first embodiment of the invention;

FIGS. 5A to 5G show cross sectional views showing steps of manufacturing a top gate type oxide semiconductor thin-film transistor according to the first embodiment of the invention;

FIG. 6 is a graph showing a relation between a continuous operation time and a threshold potential shift measured based on current-voltage characteristics of the bottom gate type oxide semiconductor thin-film transistor according to the first embodiment of the invention;

FIG. 7A is a simple schematic circuit view of a liquid crystal display device for which the first embodiment of the invention is applied;

FIG. 7B is a simple schematic circuit diagram of an organic EL display device for which the first embodiment of the invention is applied;

FIG. 8 is a graph showing a relation between a continuous operation time and a threshold potential shift measured based on current-voltage characteristics of the top gate type oxide semiconductor thin-film transistor according to the first embodiment of the invention;

FIG. 9 is a simple schematic circuit diagram of a RFID tag applied with the first embodiment of the invention;

FIGS. 10A to 10F are a cross sectional view showing manufacturing steps of an oxide semiconductor HEMT according to a second embodiment of the invention; and

FIG. 11 is a graph showing a relation between a threshold potential hysteresis and a gate length as measured based on current-voltage characteristics of an oxide semiconductor HEMT according to the second embodiment of the invention.

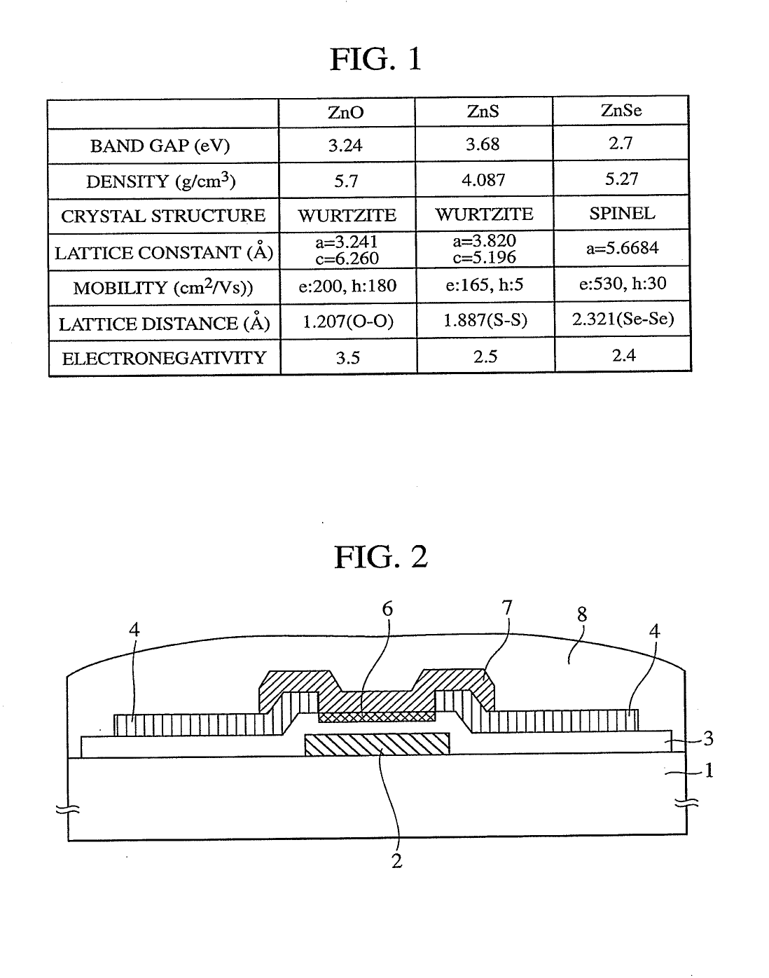

### DETAILED DESCRIPTION OF THE PREFERRED EMBODIMENT

Preferred embodiments of present invention are to be described specifically with reference to the drawings.

### First Embodiment

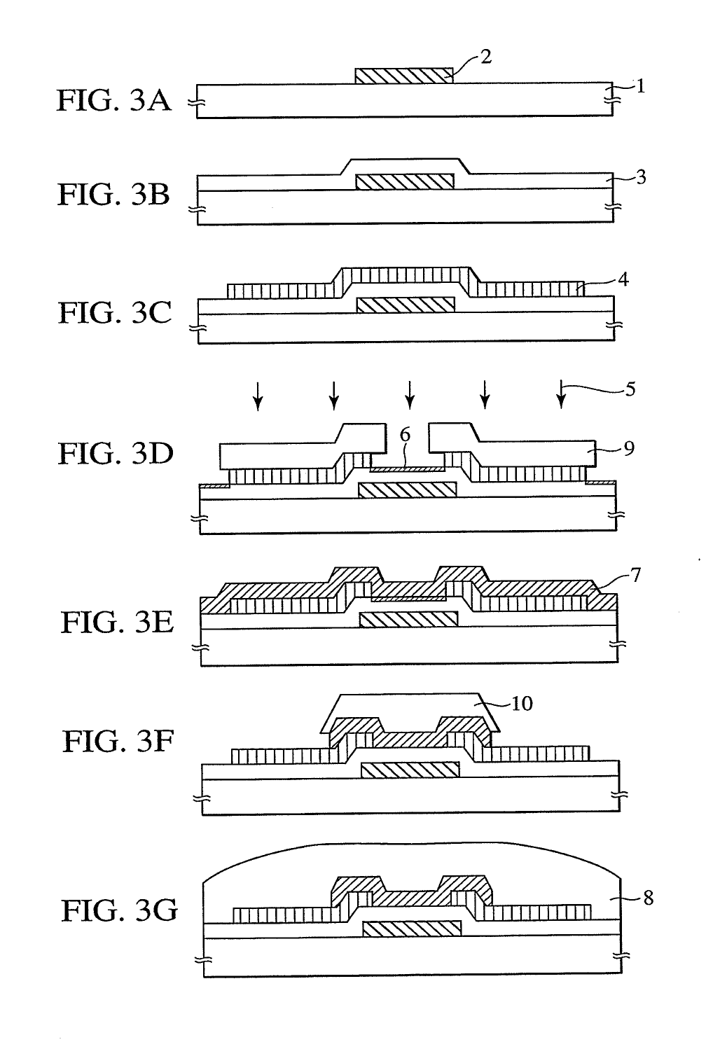

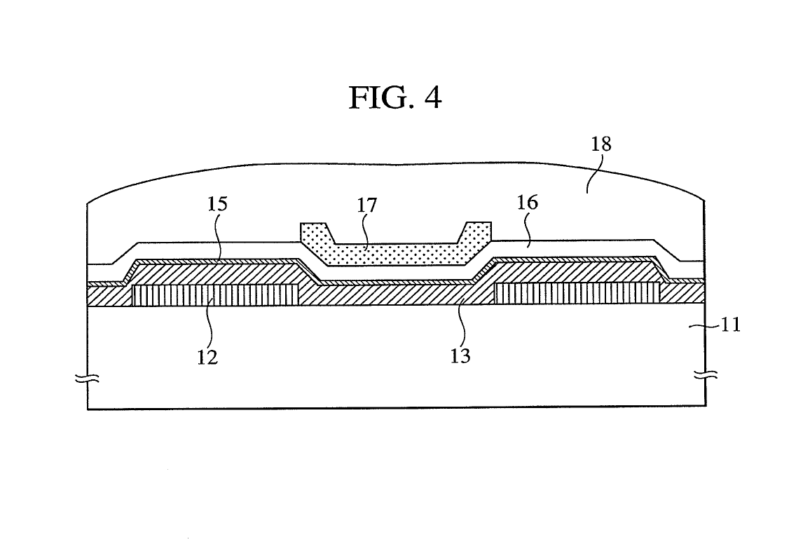

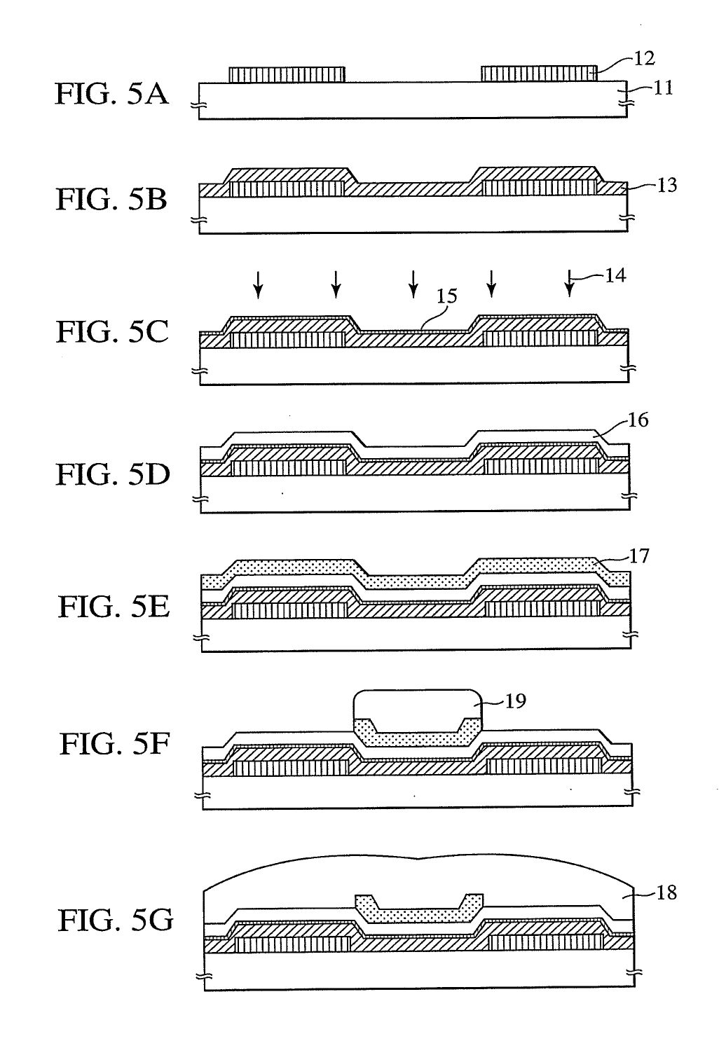

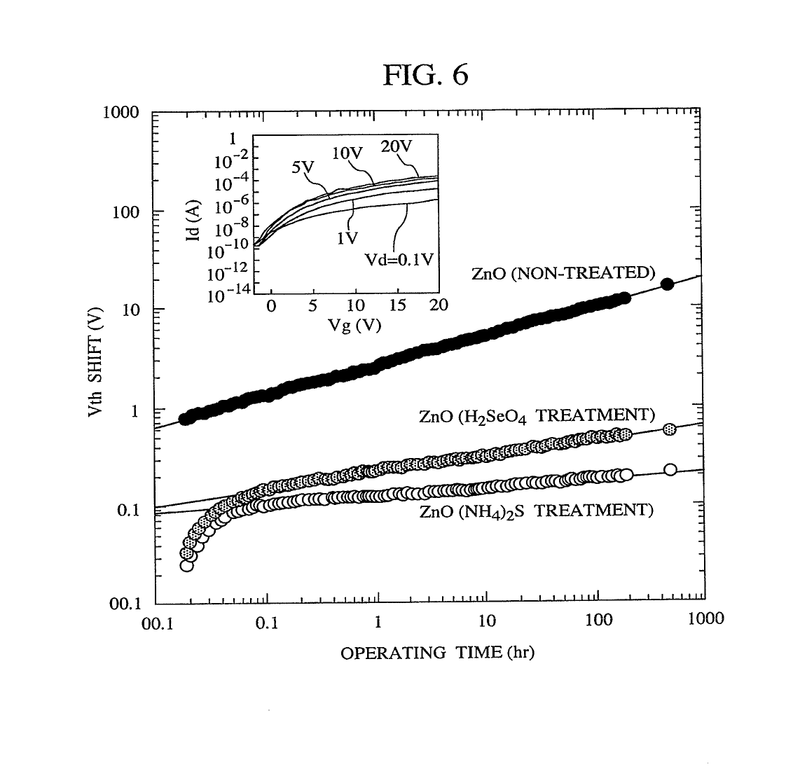

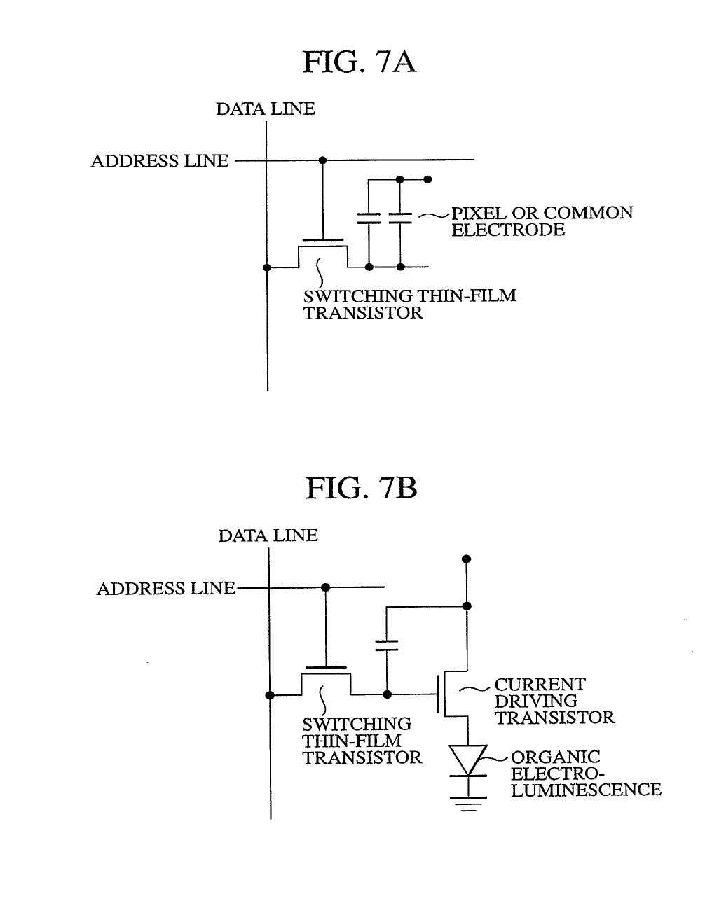

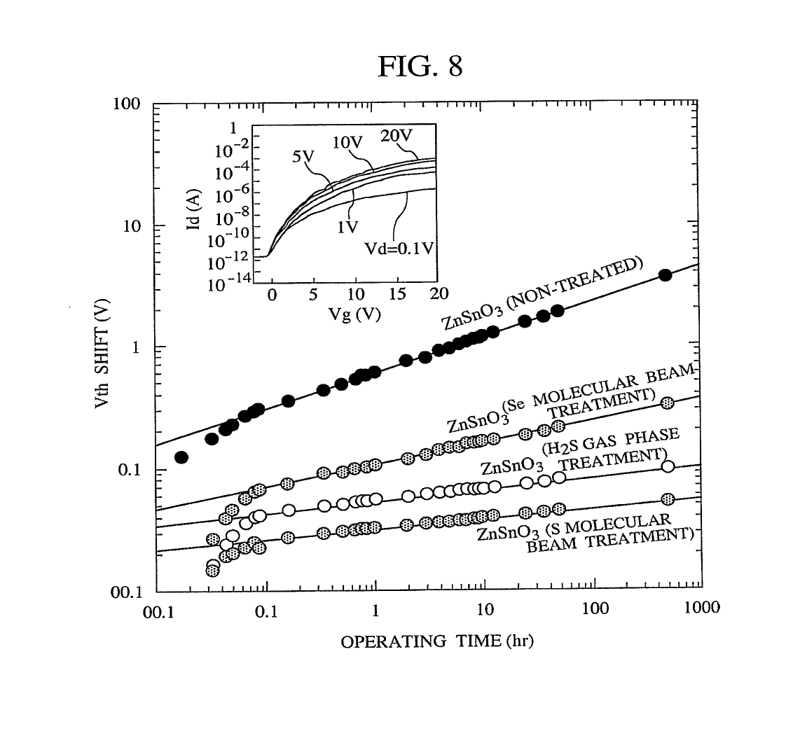

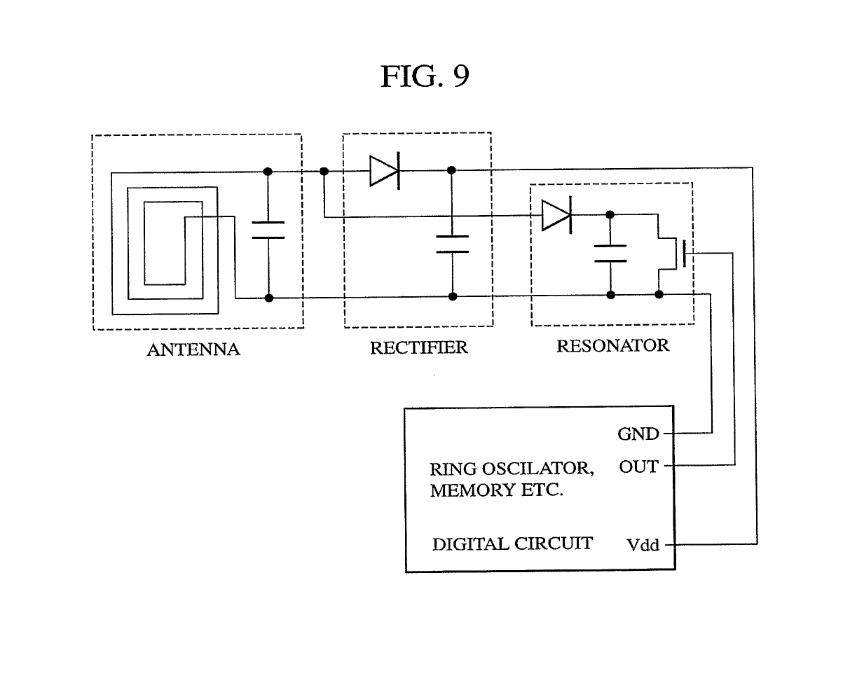

A structure of a thin-film transistor used for display and a manufacturing method according to a first embodiment of the invention are to be described with reference to FIG. 2 to FIG. 5. FIG. 2 and FIG. 3 are flow charts showing an example of cross sectional views of bottom gate type thin-film transistor and manufacturing steps thereof. FIG. 4 and FIG. 5 are flow charts showing an example of cross sectional views of top gate type thin-film transistor and manufacturing steps thereof. FIG. 6 and FIG. 8 are graphs for explaining the change with time of a threshold potential shift for showing respective effects. FIG. 7 and FIG. 9 are simple schematic views of circuits for applying them to devices respectively.

First, when a bottom gate type thin-film transistor as shown in FIG. 2 is formed, a support substrate 1, for example, a glass substrate is provided. Then, a metal thin-film as a gate electrode 2, for example, a lamination film of Al (250 nm) and Mo (50 nm) is formed by a vapor deposition method or a sputtering method on the glass substrate 1. Then, a gate insulator 3, for example, of a nitride film or an oxide film of about 100 nm thickness is deposited thereover by a sputtering method or a CVD method. Subsequently, an oxide semiconductor layer and a transparent conductive film (200 nm) such as an indium tin oxide or Ga or Al-doped zinc oxide film capable of ohmic contact with an oxide semiconductor layer is formed as a source-drain electrode 4 in such an arrangement that the gate electrode 2 is sandwiched therebetween by a vapor deposition method or a sputtering method. Usually, the transparent conductive film 4 is fabricated by wet etching with an organic acid or by dry etching with a halogen gas using a photoresist 9 or the like as a mask. Subsequent to the step, a surface treatment is performed on the surface of the gate insulator 3 with an oxygen group element such as sulfur or selenium and a compound thereof by using a surface treatment method 5 of the oxide semiconductor according to the invention.

Specific treatment methods are as described below.

(a) Gas phase method: For example, a hydrogen sulfide gas is kept in a vacuum chamber under a pressure of about 50 Pa for about 10 min, which is then once evacuated. In this step, instead of the hydrogen sulfide gas, other material gas containing sulfur or material gas containing selenium may also be used. To obtain a sufficient effect, a heat treatment at about 80° C. to 200° C. is sometimes necessary depending on the material gas. Further, instead of keeping in vacuum, substantially the same effect can be expected in view of principle also by applying a plasma treatment at a pressure of about 0.1 to 10 Pa (radical shower, ECR plasma, ion beam, sputtering using a target containing sulfur may also be used). Further, a surface passivation with a good quality can be attained also by irradiating the surface of the gate insulator 4a with a molecular beam of sulfur or selenium to by using a superhigh vacuum apparatus, although throughput is lowered.

(b) Liquid phase method: For example, after applying a treatment by dipping the surface of the gate insulator 4 with an ammonium sulfide solution, cleaning with running water and drying are performed. Substantially identical surface passivation can be performed by using other sulfur containing solution or selenium-containing solution in addition to ammonium sulfide. A high temperature condition about from 50° C. to 90° C. is sometimes necessary for conducting an effective treatment depending on the treating solution. Further, in a process in which a wet treatment is not preferred, the same effect can be obtained also by changing the solvent to an alcohol or acetone and spraying a mist of the solution containing sulfur or selenium to the surface to be treated by using a mist treatment, followed by drying.

With the surface treatment described above, the surface of the gate insulator 3 is formed into a state 6 treated with the oxygen group element such as sulfur or selenium. While a method of applying the surface treatment only to an opening portion after the fabrication of the source-drain electrode 4 has been described, same surface treatment may also be applied before deposition of the transparent conductive film as the source-drain electrode 4 with no particular problem. Further, a zinc oxide type oxide semiconductor film 7 such as of zinc oxide, zinc tin oxide, or indium zinc oxide of about 50 nm thickness is formed by a sputtering method, a CVD method, a reactive vapor deposition method or the like, and oxygen defects formed near the boundary of the oxide semiconductor layer can be suppressed by the oxygen group element such as sulfur or selenium present at the boundary to the gate insulator 3. Finally, the zinc oxide type oxide semiconductor layer 7 as a channel is fabricated by using wet etching or dry etching using a photoresist 10 or the like as a mask to complete an oxide semiconductor thin-film transistor. By further covering the surface with a passivation film 8 such as a silicon nitride film or a aluminum nitride film, an effect caused by moisture or the like present in the environment is suppressed to obtain a thin-film transistor device of high reliability.

Then, when a top gate type thin-film transistor shown in FIG. 4 is formed, a glass substrate 11 is provided for example, and a source-drain electrode 12 is formed with a transparent conductive film (250 nm) of such as indium tin oxide or Ga-doped or Al-doped zinc oxide capable of ohmic contact with an oxide semiconductor is formed thereon by using a vapor deposition method or a sputtering method. Then, a zinc oxide type oxide semiconductor film 13 of zinc oxide, zinc tin oxide, indium zinc oxide or the like of about 100 nm thickness is formed as a channel to the layer over the source-drain electrode 12 by a sputtering method, a CVD method, a reactive vapor deposition method or the like, further, a surface treatment as shown by arrows 14 is performed for the oxide semiconductor layer by using the surface treatment method of the invention. While the treatment method is basically identical with that in (a) and (b) described above, since the oxide semiconductor material is an amphoteric oxide, a sufficient care is necessary for setting treatment conditions such as a treatment temperature, a solution concentration, a treatment time, etc. so as not to progress etching by the treatment method. Then, a gate insulator 15 such as a nitride film or an oxide film of about 80 nm thickness is formed by a CVD method, a sputtering method or the like, and a gate electrode 16 comprising a metal thin film (300 nm) such as Al is formed further thereover by a vapor deposition method, a sputtering method or the like to complete a thin-film transistor. The top gate type thin-film transistor has a structure in which the oxide semiconductor layer 13 is not exposed. Therefore, the effect to the environment is less compared with that of the bottom gate structure. However, a thin-film transistor device of higher reliability can be obtained by further covering the surface with a passivation film 17 such as a silicon nitride film or an aluminum nitride film.

FIG. 6 shows the amount of shift of the threshold potential relative to the operation time as measured based on current-voltage characteristics when the bottom gate type thin film transistor is formed by using the method of the invention. In the device structure, a lamination film of Al and Mo formed by electron beam vapor deposition is used for the gate electrode 2, a silicon nitride film formed by a plasma CVD method is used for the gate insulator 3, a zinc oxide semiconductor film formed by an organic metal CVD method is used for the oxide semiconductor channel layer 7, a transparent conductive indium tin oxide film formed by a DC sputtering method is used for a source-drain electrode 4 and, further, a silicon nitride film formed by a plasma CVD method is covered entirely as the passivation film 8. The surface treatment method shown by 5 is performed by the procedure of the treatment method (a) using a 5 wt % solution of ammonium sulfide and a 2 wt % solution of selenic acid respectively and a dipping treatment was applied at 50° C. for 30 sec as the surface treatment condition. The thin-film transistor applied with the surface treatment and that with no surface treatment were compared in view of the Vth shift amount after 500 hr forecast by a continuous operation test for 200 hr. The thin-film transistor applied with surface treatment by ammonium sulfide was 0.2 V and that with surface treatment by a selenic acid solution was 0.5 V, both of them showing good results, whereas the Vth shift amount for the case with no surface treatment was 15 V. Further, a sufficient value of 10⁵ or more was obtained as a current on/off ratio and it could be confirmed that the zinc oxide thin film transistor according to the invention operated effectively as the switching application of a liquid crystal display or as a current driving device for an organic EL display. FIG. 7A shows a simple circuit constitution when thin film transistor is utilized for the liquid crystal display. FIG. 7B shows a simple circuit constitution when thin film transistor is utilized for organic EL display.

FIG. 8 shows a shift amount of the threshold potential relative to the operation time as measured based on current-voltage characteristics when a top gate type thin-film transistor was formed by using the method of the invention. In the device structure, a transparent conductive Al-doped zinc oxide film formed by a DC sputtering method was used for the source-drain electrode 12, a zinc tin oxide semiconductor film formed by an RF sputtering method was used for the oxide semiconductor channel layer 13, a silicon oxide film formed by an atmospheric pressure CVD method was used for the gate insulator 16, an Al film grown by a DC sputtering method was used for the gate electrode 17, and the entire portion was protected by a passivation film 18 by an aluminum nitride film. A good value of 10⁹ or more is obtained as a current on-off ratio for the present device, and the reliability can be further improved by utilizing the surface treatment of the invention. As the actually used surface treatment, the surface treatment was performed by a method of using a gas phase method while keeping a hydrogen sulfide gas in a vacuum chamber at a room temperature at a pressure of about 3×10⁴ Pa for 30 min. Further, the treatment was performed also by a molecular beam treatment of sulfur and selenium in a superhigh vacuum chamber. Referring to the result by the Vth shift amount after 500 hr forecast by a continuous operation test for 100 hr, while it was 3.2 V with no surface treatment, it was 0.1 V with a hydrogen sulfide gas phase treatment, 0.05 V with a sulfur molecular beam treatment, and 0.3 V with selenium molecular beam treatment, each of which showed a good value. Also for a current off/off ratio, a good value of 10⁹ or more was obtained, as well as a good performance of the mobility of 50 to 100 cm²/Vs was obtained for the top gate structure in which control for oxide semiconductor crystals is relatively easy. Also in conjunction with the stable operation of the zinc tin oxide thin film transistor according to the invention, applicability to a passive RFID capable of operating at 13.56 MHz, not only to the device for liquid crystal display or organic EL display can be shown.

FIG. 9 shows a simple constitution. An RFID tag which is substantially transparent and capable of operating at 13.56 MHz comprising an antenna, a rectifier circuit, a radio frequency circuit, a memory, etc. can be attained by forming circuits other than the antenna by using a zinc oxide type oxide semiconductor of high mobility and, further, utilizing a transparent conductive Ga or Al-doped zinc oxide film also for the antenna.

### Second Embodiment

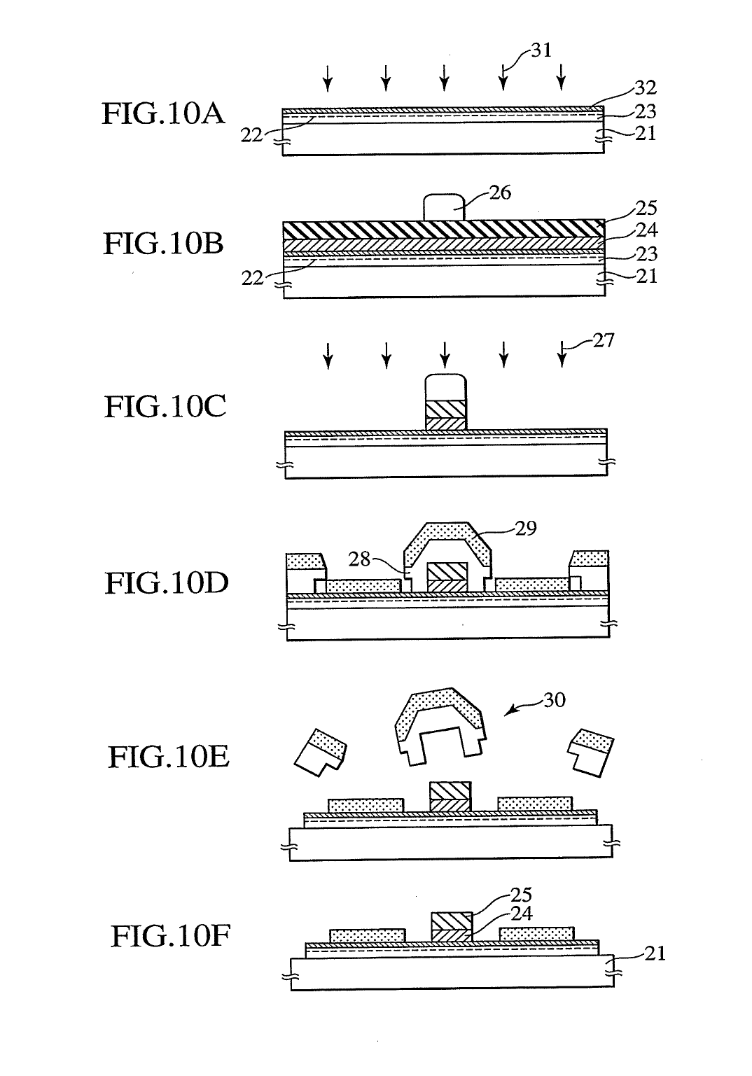

Description is to be made to the structure of an HEMT (High Electron Mobility Transistor) and a manufacturing method according to a second embodiment of the invention with reference to FIG. 10.

First, a combination of a band structure so as to form a two dimensional electron gas layer 22 is selected and, for example, a multi-layer film 23 comprising, for example, zinc magnesium oxide/zinc oxide/zinc magnesium oxide is grown crystallographically by an MBE method or an MO (metal Organic) CVD method, a PLD (Pulsed Laser Deposition) method or the like above a semiconductor substrate 21 such as a sapphire substrate or a zinc oxide substrate. When the effect due to a substrate material or a polar surface is controlled, a buffer layer such as a zinc oxide layer or a zinc magnetic oxide layer grown on the surface of a semiconductor substrate at a low temperature condition of 200° C. or lower is sometimes disposed between the multi-layer structure 23 and the substrate 21. A gate insulator 24 is formed on the multi-layer structure crystals 23 by a CVD method, a sputtering method, a reactive vapor deposition method or the like, a gate electrode 25 is further formed by a vapor deposition method, a sputtering method or the like, and the gate electrode 25 to the gate insulator 24 are fabricated by a dry etching method or a milling method 27 by using a photoresist, etc. as a mask 26. Then, after forming a photoresist mask 28, a source-drain electrode layer 29 is formed by a vapor deposition method, a sputtering method or the like, and the source-drain electrode is fabricated by the lift off method 30 (alternatively, the photo-step may be applied subsequently and the source-drain electrode may be fabricated by etching) to complete the HEMT device. In the process, an oxide semiconductor surface treatment method shown by 31 of the invention is applied just before forming the gate insulator 24. While the method of treatment is basically identical with the treatment method described (a) and (b) in the first embodiment, when the treatment is performed by using the gas phase treatment method of the invention, particularly, the molecular beam method continuously after growing of the multi-layer structure crystal 22 by an MBE method, an MOCVD method, or a PLD method in one identical superhigh vacuum chamber or a different super high chamber, it needs less number of treatment steps and is more effective.

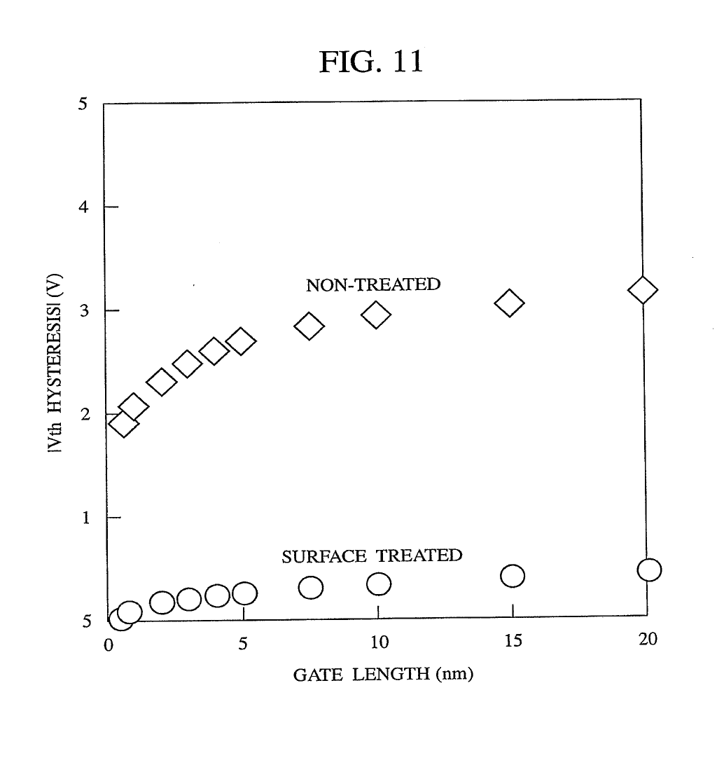

Actually, by using a multi-layer structure crystals formed by MBE growing in the order of a zinc magnesium oxide barrier layer (300 nm), a zinc oxide channel layer (20 nm), and a zinc magnesium oxide cap layer (85 nm) above zinc oxide single crystal substrate, Al₂O₃ layer formed by a sputtering method as a gate insulator (50 nm), an Au (250 nm)/Ti(10 nm) multi-layer film as a gate electrode formed by an electron beam vapor deposition method, and an Au (250 nm)/Mo (10 nm) film formed as a source-drain electrode by an electron beam vapor deposition method are prepared. FIG. 11 shows the result of comparing the Vth hysteresis characteristics between a case where an aluminum oxide layer of the gate insulator is formed after treating the surface of the multi-layered crystal structure by using a gas phase treatment method using a hydrogen sulfide gas of the invention at 50° C., 20×10⁴ Pa for 10 min and the non-treated case.

It can be confirmed that the Vth hysteresis is about 2 to 3V in the non-treated case, whereas it is suppressed within a range from 0 to 0.5V, where the surface treatment of the invention is applied. It is considered that the Vth hysteresis is a phenomenon caused by movement of some or other mobile ions in the gate insulator or the oxide semiconductor by way of oxygen defects in the oxide semiconductor. Naturally, it is desirable that the Vth hysteresis characteristics are small for the suppression of scattering of the device characteristics or stable operation, and an insulator such as of hafnium oxide, which can be controlled easily for the boundary but is difficult to be fabricated, has been used sometimes so far.

However, it has been confirmed that the oxygen defects between the gate insulator and the oxide semiconductor are suppressed by the surface treatment method of the invention, and this can be put to practical use sufficiently with an aluminum oxide or silicon oxide film used in usual semiconductor processes. A power device, a sensor device, etc. utilizing the wide gap or the high exciton binding energy characteristics of the oxide semiconductor can be expected to be put to practical use by the method. As the characteristics of the HEMT device of 1 gate length, 80 mS/mm of gm (mutual conductance) and a mobility of 135 cm²/Vs can be obtained. While description has been made in this embodiment to a lateral type field effect transistor, oxygen defects can be decreased by the surface treatment of the invention and additional effects such as decrease in the leak current can be expected also in devices, for example, LED, LD, or a vertical structure transistor such as a bipolar transistor in which a boundary is present between an oxide semiconductor and a dielectric film.

While the invention proposed by the present inventors has been described specifically with reference to the embodiments, it is to be understood that the invention is not restricted to such embodiments and can be modified variously within a range not departing the gist thereof.

A manufacturing method of the semiconductor device according to the invention is applicable to the quality control of semiconductor products having a polycrystal silicon film.

Description of reference numerals described in the drawings attached in the present application is as follows:
1 support substrate
2 gate electrode
3 gate insulator
4 source-drain electrode layer
5 surface treatment of the invention
6 surface treated layer of the invention
7 oxide semiconductor layer
8 passivation layer
9 source-drain electrode resist pattern
10 gate electrode resist pattern
11 support substrate
12 source-drain electrode layer
13 oxide semiconductor layer
14 surface treatment of the invention
15 surface treated layer of the invention
16 gate insulator
17 gate electrode layer
18 passivation layer
19 gate electrode resist pattern
21 semiconductor substrate
22 two dimensional electron gas layer
23 oxide semiconductor active layer
24 gate insulator
25 gate electrode layer
26 gate electrode resist pattern
27 gate fabrication treatment
28 resist pattern for lift off
29 source-drain electrode layer
30 lift off process
31 surface treatment of the invention
32 surface treated layer of the invention

What is claimed is:

1. An oxide semiconductor device comprising:
a substrate;
a channel layer disposed above the substrate and comprised of a zinc-containing semiconductor;
a source-drain electrode layer disposed in contact with both end portions of the channel layer so as to sandwich the channel layer;
a gate insulator including a first face disposed in contact with one surface of the channel layer and further including a second face opposite to the first face; and
a gate electrode disposed on the second face of the gate insulator, wherein the gate electrode is configured to provide an electric field to the channel layer by way of the gate insulator,
wherein said one surface of the channel layer is subjected to a surface treatment using at least one of sulfur and selenium so that said at least one of sulfur and selenium is substituted for oxide defects formed in the channel layer comprised of the zinc-containing semiconductor at and adjacent to a boundary where the gate insulator and the channel layer are in contact with each other.

2. The oxide semiconductor device according to claim 1, wherein the atom concentration of sulfur or selenium is within a range of 10¹⁶ cm⁻³ or more and 10²⁰ cm⁻³ or less.

3. The oxide semiconductor device according to claim 1, wherein the channel layer comprises an oxide semiconductor at least containing zinc, or a lamination layer comprising several kinds of the zinc oxide type oxide semiconductors in combination.

4. The oxide semiconductor device according to claim 1, comprising a bottom gate type structure in which the gate electrode layer is disposed on the surface of the substrate and the source-drain electrode layer is disposed on the remote side from the gate electrode relative to the substrate.

5. The oxide semiconductor device according to claim 1, comprising a top gate type structure in which the source-drain electrode layer is disposed on the surface of the substrate and the gate electrode layer is disposed to the substrate on the remote side from the gate electrode relative to the substrate.

6. An oxide semiconductor device comprising:
a substrate;
a channel layer disposed above the substrate and comprised of a zinc-containing semiconductor;
a source-drain electrode layer disposed in contact with both end portions of the channel layer so as to sandwich the channel layer;
a gate insulator including a first face disposed in contact with one surface of the channel layer and further including a second face opposite to the first face; and
a gate electrode disposed on the second face of the gate insulator, wherein the gate electrode is configured to provide an electric field to the channel layer by way of the gate insulator; and
surface treatment means provided at said one surface of said channel layer for substituting at least one of sulfur and selenium for oxide defects formed in the channel layer comprised of the zinc-containing semiconductor at and adjacent to a boundary where the gate insulator and the channel layer are in contact with each other.

7. The oxide semiconductor device according to claim 6, wherein the atom concentration of sulfur or selenium is within a range of 10¹⁶ cm⁻³ or more and 10²⁰ cm⁻³ or less.

8. The oxide semiconductor device according to claim 6, wherein the channel layer comprises an oxide semiconductor at least containing zinc, or a lamination layer comprising several kinds of the zinc oxide type oxide semiconductors in combination.

9. The oxide semiconductor device according to claim 6, comprising a bottom gate type structure in which the gate electrode layer is disposed on the surface of the substrate and the source-drain electrode layer is disposed on the remote side from the gate electrode relative to the substrate.

10. The oxide semiconductor device according to claim 6, comprising a top gate type structure in which the source-drain electrode layer is disposed on the surface of the substrate and the gate electrode layer is disposed to the substrate on the remote side from the gate electrode relative to the substrate.

11. An oxide semiconductor device comprising;
a substrate;
a channel layer disposed above the substrate and comprised of a zinc-containing semiconductor;
a source-drain electrode layer disposed in contact with both end portions of the channel layer so as to sandwich the channel layer;
a gate insulator including a first face disposed in contact with one surface of the channel layer and further including a second face opposite to the first face; and
a gate electrode disposed on the second face of the gate insulator, wherein the gate electrode is configured to provide an electric field to the channel layer by way of the gate insulator; and
wherein at least one of sulfur and selenium is used as a surface treatment at said one surface of the channel layer as a substitution element for oxygen defects which are present formed in the channel layer comprised of the zinc-containing semiconductor between the gate insulator and the channel layer.

12. The oxide semiconductor device according to claim 11, wherein the atom concentration of sulfur or selenium is within a range of 10¹⁶ cm⁻³ or more and 10²⁰ cm⁻³ or less.

13. The oxide semiconductor device according to claim 11, wherein the channel layer comprises an oxide semiconductor at least containing zinc, or a lamination layer comprising several kinds of the zinc oxide type oxide semiconductors in combination.

14. The oxide semiconductor device according to claim 11, comprising a bottom gate type structure in which the gate electrode layer is disposed on the surface of the substrate and the source-drain electrode layer is disposed on the remote side from the gate electrode relative to the substrate.

15. The oxide semiconductor device according to claim 11, comprising a top gate type structure in which the source-drain electrode layer is disposed on the surface of the substrate and the gate electrode layer is disposed to the substrate on the remote side from the gate electrode relative to the substrate.

16. The oxide semiconductor device according to claim 1, wherein the gate insulator is comprised of one of silicon nitride or silicon oxide.

17. The oxide semiconductor device according to claim 12, wherein the gate insulator is comprised of one of silicon nitride or silicon oxide.

18. The oxide semiconductor device according to claim 17, wherein the gate insulator is comprised of one of silicon nitride or silicon oxide.
